(19) United States
(12) Patent Application Publication
(10) Pub. No.: US 2017/0242172 A1
(43) Pub. Date: Aug. 24, 2017

(54) POLARISING PHOTOVOLTAIC MODULE BUILT INTO THE SCREEN OF AN ELECTRONIC DISPLAY DEVICE

(71) Applicant: SUNPARTNER TECHNOLOGIES, Aix En Provence (FR)

(72) Inventors: Badre KERZABI, Aix En Provence (FR); Cyril CHAPPAZ, Aix En Provence (FR)

(73) Assignee: SUNPARTNER TECHNOLOGIES, Aix En Provence (FR)

(21) Appl. No.: 15/518,399

(22) PCT Filed: Oct. 13, 2015
(86) PCT No.: PCT/FR2015/000195

§ 371 Date: Apr. 11, 2017

(30) Foreign Application Priority Data
Oct. 15, 2014 (FR) 14 02316

(51) Int. Cl. G02B 5/30; H01L 31/0475; H01L 27/15; G02F 1/1335; H01L 27/28

(52) U.S. Cl. CPC G02B 5/3058; G02F 1/133528; G02F 1/1336; H01L 27/288; H01L 27/156; H01L 31/0475; G02F 2001/133548; G02F 2001/133618; H01L 51/5293

(57) ABSTRACT

A display device provided with a polarising photovoltaic module includes (a) a plurality of polarisers; (b) a plurality of pixels which emit or transmit light referred to as image light; (c) a plurality of photovoltaic active zones and a plurality of openings, two adjacent photovoltaic active zones forming an opening and said photovoltaic active zones being arranged between the pixels and the polarisers; wherein said polarisers are semi-reflective and are made up of one or more surfaces selected among planar surfaces, which are concave or convex, and have parabolic, conical, pyramidal, tetrahedral, semi-cylindrical or cylindrical-parabolic shapes, said polarisers being arranged so as to concentrate, by reflection, a first linear polarised component of the ambient light onto said photovoltaic active zones, as well as to transmit, through the polarising photovoltaic module, a second linear polarised component of the ambient light or of the image light.

### FIELD OF THE INVENTION

The present invention relates to emissive, reflective or transflective screens forming part of electronic display devices containing one or more polarizers and integrating a semitransparent photovoltaic module.

### PRIOR ART

In the present invention, the expression “display device” refers to an electronic device equipped with a screen that allows a luminous message or image to be displayed by suitably guiding the light generated by said device (emissive screens) and/or the ambient light (reflective and transflective screens).

The majority of these screens are liquid-crystal or electroluminescent screens that generally contain one or two polarizers. The two performance criteria for a polarizer are firstly to maximize the transmittance of a first linearly polarized component of the incident light and secondly to maximize the extinction coefficient, that it to say the transmittance ratio between the first linearly polarized component and the second linearly polarized component (orthogonal to the first). Thus, an ideal polarizer would allow all of the first linearly polarized component of the incident light to pass and block (by absorption or reflection) all of the second linearly polarized component.

The standard polarizers that are most commonly used in display devices are organic polarizers, which transmit around 85% of a first linearly polarized component and absorb more than 99% of the second. In order to improve the efficiency and decrease the thickness of said organic polarizers, other, inorganic, types of polarizers, commonly called wire-grid polarizers (WGPs), have been developed. These consist of a multiplicity of reflective metal strips separated by openings the widths of which are smaller than the wavelengths of visible light, WGPs differing from organic polarizers in that they reflect the second linearly polarized component, hence their designation as semi-reflective or transflective polarizers. Only their cost remains an obstacle to their use, but roll-to-roll manufacturing processes are lowering this cost.

Combining a transflective polarizer with a wafer-scale photovoltaic module placed below said polarizer allows one of the standard polarizers and the rear reflector used in such screens to be replaced, while producing electrical energy. However, in such a system, 50% of the ambient light is lost in the first polarizer, the remaining 50% being either reflected or transmitted by the second transflective polarizer depending on whether the pixel is in the light or dark state. Thus, on average only 25% of the ambient light is converted to electricity by the photovoltaic module. Moreover, depending on the image displayed by the screen, the luminous intensity received by the photovoltaic module is not uniform across all of its surface, which poses a problem in the case of said photovoltaic module consisting of cells connected in series. Specifically, if one of the cells is exposed to a level of illumination that is lower than that of the other cells, the drop in the production of electricity by this cell will affect all of the other cells, since the electric current will be decreased in the same way in all of the cells connected in series.

Another approach, compatible with any of the aforementioned types of screens, consists of directly structuring, on the nanoscale, a photovoltaic material in the form of a wire grid so that it acts as a polarizer while producing electrical energy by converting the linearly polarized component of the non-transmitted light (publication Journal of Optics A: Pure and Applied Optics, 2008, vol. 10, p. 44014—University of Tokyo). However, the manufacture of such a structure requires a command of nanoscale etching using complex and expensive methods which are thus difficult to apply on an industrial scale. Moreover, there is a necessary trade-off to be made between the efficiency of polarization and the efficiency of photovoltaic conversion, in particular by varying the thickness of the manufactured nanostructures. The performance levels that are currently achievable are very low, with a conversion efficiency of 0.2% and an extinction coefficient of around 5, which proves the concept but remains insufficient for incorporation into a screen.

One variant consists of producing the polarizer and the photovoltaic absorber on the basis of the anisotropic structuring of one and the same mixture of organic materials (patent WO2012142168 and publication Advanced Materials, 2011, vol. 23, p. 4193—University of California Los Angeles). The main advantage of this variant is the intrinsic recovery of light energy from one of the two linearly polarized components of the ambient light (that which is lost through absorption in standard organic polarizers) in order to produce electrical energy. However, in order to be effective, the organic photovoltaic material absorbs at least part of the visible electromagnetic spectrum, resulting in this photovoltaic module being imbued with a colored aspect which would substantially alter the colorimetry of the screen into which it is incorporated.

### AIMS OF THE INVENTION

The main aim of the present invention is to propose a polarizing photovoltaic module capable of recovering and using light energy from the linearly polarized component absorbed by the polarizer in order to convert it to electrical energy, while minimizing the impact of the integration of such a module (i.e. one that is both polarizing and photovoltaic) on the quality of the image displayed by the screen.

Another aim of the invention is to produce electrical energy independently of the light or dark state of the pixels.

### SUBJECTS OF THE INVENTION

The subject of the invention relates to a display device, a method for producing a portion of the device, and a unit including such a device.

The display device according to the invention is provided with a polarizing photovoltaic module which includes at least:
(a) a plurality of polarizers;
(b) a plurality of pixels which emit or transmit light referred to as image light;
(c) a plurality of photovoltaic active zones and a plurality of openings, two neighboring photovoltaic active zones forming an opening and said photovoltaic active zones being positioned between the pixels and the polarizers;

said device being characterized in that said polarizers are semi-reflective and consist of one or more surfaces chosen from among planar, concave or convex surfaces which are parabolic, conical, pyramidal, tetrahedral, semicylindrical or cylindro-parabolic in shape, said polarizers being arranged so as both to concentrate, by reflection, a first linearly polarized component (P1) of the ambient light (5′) onto said photovoltaic active zones and to transmit, through the polarizing photovoltaic module, a second linearly polarized component (P2) of the ambient light or of the image light.

Said polarizers are composed of an array of reflective strips, the widths of which and the distances separating them are advantageously less than 400 nanometers. The reflective strips are generally parallel to one another and made of metal, for example of silver, of aluminum or of copper. They may also consist of multiple metal layers deposited successively on top of one another.

A light concentrator is defined as an optical concentrator that is capable of collecting the light of a light beam having various angles of incidence in a spatial zone referred to as an “entrance surface” in order to guide it toward a smaller surface referred to as an “exit surface” and generally corresponding to the top of the concentrator. The degree of concentration of the light concentrator is then defined as the ratio of the exit surface to the entrance surface.

In the present invention, the semi-reflective light concentrators allow, by way of multiple reflections, a first linearly polarized component (P1) of the ambient light to be guided toward the photovoltaic active zones for the purpose of producing electrical energy. Thus, the tops of the concentrators must be positioned facing the active zones of the photovoltaic module such that the majority of said first linearly polarized component of the ambient light focused by said concentrators is directed onto the photovoltaic active zones.

The plurality of photovoltaic active zones may form a single photovoltaic cell or an assembly of cells that are electrically connected in series or in parallel in order to form a photovoltaic module. It may also be a plurality of independent modules or cells. Generically, the expression “photovoltaic module” will be used below to refer to any one of these configurations. Said photovoltaic active zones may be active on one or more faces and consist of one or more active materials that may be inorganic or organic, crystalline or amorphous or opaque or semitransparent. These active materials are advantageously thin films based on amorphous or microcrystalline silicon, GaAs (gallium arsenide), CdTe (cadmium telluride), GIGS (copper/indium/gallium/selenium), CZTS (copper/zinc/tin/selenium) or based on polymers. It may be a p-i-n or p-n junction or else tandem cells, i.e. cells including two superposed cells that preferentially absorb a different portion of the electromagnetic spectrum. They may be designed to convert visible light and/or ultraviolet light and/or infrared light to electricity.

According to a certain embodiment of the device according to the invention, said photovoltaic active zones are positioned in the vicinity of the plane of maximum concentration of said polarizers. This configuration optimizes the amount of ambient light directed onto the photovoltaic active zones, and thus allows the production of electricity by the photovoltaic module to be maximized. In practice, the amount of ambient light concentrated onto the active zones depends in particular on the angle of incidence of the ambient light on the surface of the polarizers, a portion of the light being lost through reflection off the surface of the concentrator and away from the device. Specifically, all the concentrators have a constrained cone of acceptance of incident light, i.e. a limit angle of incidence beyond which the incident light is no longer focused but expelled from the optical system. This acceptance cone depends on the shape of the concentrators and becomes increasingly limited as the degree of concentration increases, i.e. as the ratio of the entrance surface of the light flux to the exit surface of the light flux increases.

According to another embodiment, the plurality of pixels are separated from one another by an inter-pixel matrix and the photovoltaic active zones are aligned with said inter-pixel matrix so as to decrease Moire phenomena, which are well known to those skilled in the art, as far as possible.

According to an additional variant embodiment of the device, the photovoltaic active zones and the polarizers are organized into a continuous or discontinuous array of elementary patterns, defining any type of shape, in particular curved shapes, for example circular shapes, and/or planar shapes, for example polygonal, prismatic or hexagonal shapes. In this case, a pitch of the array of photovoltaic active zones that is tailored to accord with the pitch of the inter-pixel matrix may advantageously be chosen in order to decrease moire phenomena as far as possible.

According to various embodiments, said pixels may consist of electro-optical modulators, optionally combined with color filters, or of electroluminescent materials. Electro-optical modulators allow the luminosity of the pixel to be adjusted and the color filters are typically red, green and blue (RGB) for an additive technology and cyan, magenta and yellow (CMY) for a subtractive technology. The additive RGB technology is coupled for example with a liquid-crystal modulator in liquid-crystal display devices, while the subtractive CMY technology is implemented in devices employing modulators referred to as electrowetting modulators.

According to various embodiments, the image light corresponds to a portion of the ambient light that is fully or partially reflected in the device and/or a portion of the light emitted by the device. In the case of an emissive liquid-crystal display (LCD) device, the light emitted by the device may be produced by one or more, generally white, light-emitting diodes (LEDs) which are located directly facing the device that is a subject of the invention, or else on the side of a transparent waveguide through which the light is propagated. In the case of an OLED display device, the emitted light is produced by a plurality of organic electroluminescent sources which preferably emit in a portion of the visible spectrum.

According to various embodiments, the display device additionally includes one or more other polarizers and/or a quarter-wave plate being used to polarize the image light. These polarizers, for example organic or wire-grid polarizers, are incorporated into known LCD or OLED devices. The module of the display device according to the invention comprising the polarizers and the photovoltaic active zones may be laminated on top of the last polarizer and/or the quarter-wave plate of said device. Alternatively, it may replace the last polarizer in order to avoid using an additional polarizing surface and to decrease the thickness of said display device.

In another particular embodiment (not shown), the display device additionally includes a functional surface, for example an antireflective, anti-UV or touch-sensitive surface.

According to an exemplary method for manufacturing a portion of the display device according to the invention composed of concentrators and photovoltaic active zones, the following steps are carried out:
(a) a semitransparent photovoltaic module composed of a plurality of photovoltaic active zones and a plurality of openings is provided, said photovoltaic active zones consisting of a plurality of thin films deposited on a transparent substrate;
(b) a first transparent resist layer is deposited then structured so as to form the geometry of the concentrators;
(c) a conformal layer of a reflective material is deposited on the structured face of said resist;
(d) the entire surface of the reflective layer is etched in the form of strips, and the surface at the tops of the concentrators is also etched;
(e) a second, planarizing layer of transparent resist is deposited.

The transparent substrate of the semitransparent photovoltaic module generally consists of a solid transparent material such as glass or else a polymer such as PMMA, PET or polycarbonate, and has a refractive index close to 1.5. Advantageously, the refractive index of the first transparent resist layer is identical to that of the transparent substrate. In this manufacturing process, the first transparent resist layer may be structured under UV irradiation, using rollers or textured stamps that imprint an array of shapes onto a light-sensitive liquid or semi-liquid polymer, or by embossing a solid transparent material. The step of etching the reflective layer may be carried out by means of a photolithography process or by laser. The refractive index of the second resist layer should be optimized in accordance with that of the first resist layer so as to limit the total reflections at the interfaces, as well as in accordance with the shape of the concentrators so as to maximize the angle of acceptance of incident light.

### FIGURES

The invention will be better understood from its detailed description, provided with reference to the figures in which:

FIGS. 1a and 1b are schematic representations in cross section of a portion of the display device according to the invention and illustrate its operation;

FIG. 2 is a schematic representation in cross section of the structure of an emissive LCD display device according to the invention;

FIG. 3 is a schematic representation in cross section of the structure of a reflective LCD display device according to the invention;

FIG. 4 is a schematic representation in cross section of the structure of an OLED display device according to the invention.

The figures are not to scale, the relative thicknesses of the components of the device being intentionally exaggerated in order to provide a clearer representation of its structure.

### DETAILED DESCRIPTION

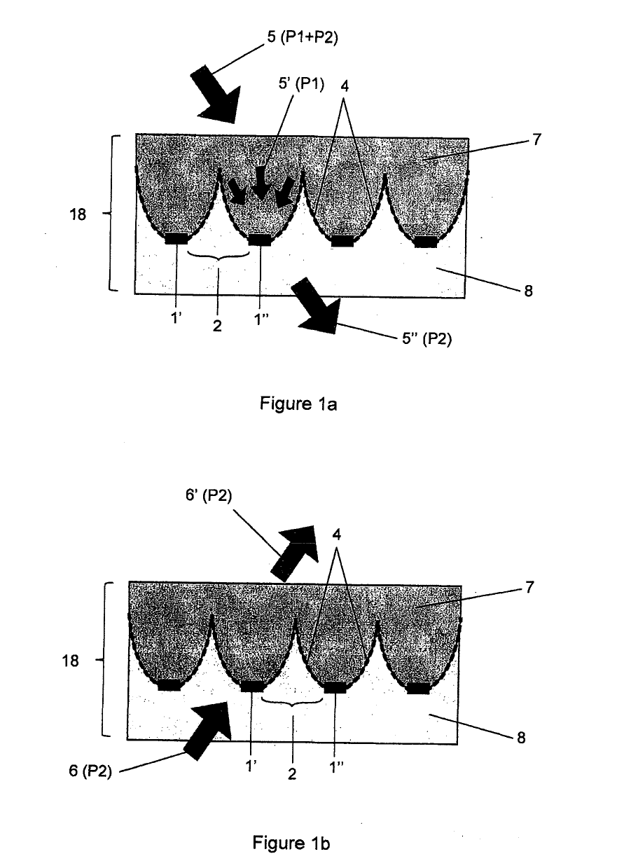

Reference is made to FIGS. 1a and 1b, which are schematic representations in cross section of a portion of the display device according to the invention, referred to as a polarizing photovoltaic module 18. Said polarizing photovoltaic module 18 includes a plurality of photovoltaic active zones 1, two neighboring photovoltaic active zones 1′, 1″ forming an opening 2, and a plurality of semi-reflective polarizers 4 that are parabolic in shape. Generally consisting of a set of metal strips of controlled size, said polarizers 4 are arranged at the interface between two layers of transparent materials 7, 8 which ideally have identical, or nearly identical, refractive indices so as to limit the phenomena of total reflection of the light passing through this interface.

As shown in FIG. 1a, the polarizers 4 reflect a first linearly polarized component 5′ of the ambient light 5 emitted by natural or artificial light sources that are external to the device (hence not polarized before reaching the device) and transmit a second linearly polarized component 5″, orthogonal to the first, through the polarizing photovoltaic module 18. By virtue of their parabolic shape, the polarizers 4 act as concentrators of a portion of the ambient light 5 by way of multiple reflections of its first linearly polarized component 5′. They are positioned with respect to the photovoltaic active zones 1 so that said first linearly polarized component 5′ of the ambient light 5 is directed by the light concentrators 4 onto said photovoltaic active zones 1.

FIG. 1b illustrates the operation of the polarizing photovoltaic module 18 with respect to the image light 6 emitted by the display device, which light is generally polarized at the output of emissive or reflective LCD and OLED devices. It is assumed here that the components allowing the display are oriented such that the image light 6 corresponds to the second linearly polarized component P2. In the case of an ideal interface, all of the polarized image light 6 is transmitted through the semi-reflective polarizers 4. In practice, reflection or absorption loss phenomena occurring successively in the layers 8, 4, 7 limit the amount of transmitted light 6′ to around 90% of the amount of light 6 arising from the image. Furthermore, a portion of the image light 6 is reflected or absorbed by the back face of the photovoltaic active zones 1. However, for a given level of production of electricity, the surface fraction of said photovoltaic active zones 1 is smaller with respect to a standard device without light concentrators 4, thereby allowing the total quantity of transmitted image light 6′ to be increased.

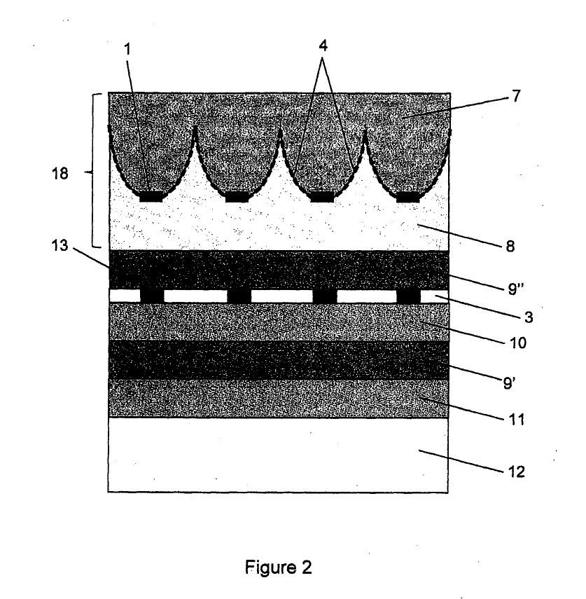

The polarizing photovoltaic module 18 may be incorporated into a display device, either in addition to the components allowing an image to be displayed or by replacing the last linear polarizer through which the image light 6 passes. The cases of use described in FIGS. 2 to 4 make reference to three different display devices in which the polarizing photovoltaic module 18 replaces the last linear polarizer that is usually incorporated into such devices.

FIG. 2 is a schematic representation in cross section of the structure of an emissive LCD display device according to the invention. Said device consists, inter alia, of a backlight 12 allowing light to be produced via LED illumination and a first linear polarizer 11 that polarizes the light arising from the backlight 12. The plane of polarization of the light may be altered by means of an electro-optical modulator 10 (a liquid-crystal electro-optical modulator in the present case) controlled by means of two transparent electrodes that are deposited on glass substrates 9′, 9″. The pixels 3 alternately consist of three color filters, typically red, green and blue, and are separated by an inter-pixel matrix 13. The polarizing photovoltaic module 18 acts as the upper polarizer. In order to maximize transmission and to limit the moire phenomena known to those skilled in the art as far as possible, a pitch of the array of photovoltaic active zones 1 is chosen so as to accord with the pitch of the inter-pixel matrix 13.

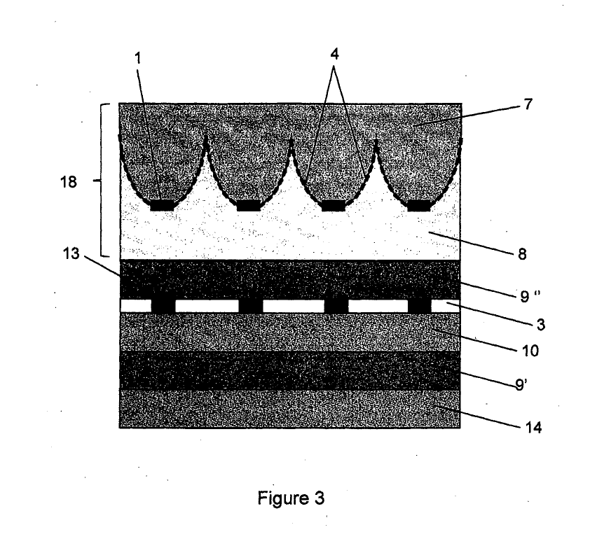

FIG. 3 is a schematic representation in cross section of the structure of a reflective LCD display device according to the invention. The composition of such a device differs from that described in FIG. 2 in that the backlight and the first polarizer are replaced by a mirror 14. The image light 6 corresponds to the ambient light that is reflected by the mirror 14 and passes through the pixels 3. Again in this case, the polarizer that is positioned as standard above the upper electrode 9″ of such a device is replaced by the polarizing photovoltaic module 18.

A concrete exemplary embodiment is described below. On the basis of a display device containing an array of pixels 3 of 150 μm in width separated from one another by an inter-pixel distance 13 of 30 μm, a photovoltaic module formed from an array of photovoltaic active strips 1 of 10 μm in width, separated by openings of 20 μm, is provided. The structured transparent substrate 8 has a refractive index close to 1.5. The polarizers 4 are in the shape of truncated parabolas with an entrance surface of 30 μm in width and a height of between 20 and 40 μm. In the case of the planarizing transparent resist 7 having a refractive index close to 1.5, the angle of acceptance of ambient light incident on the surface of said device is 60°.

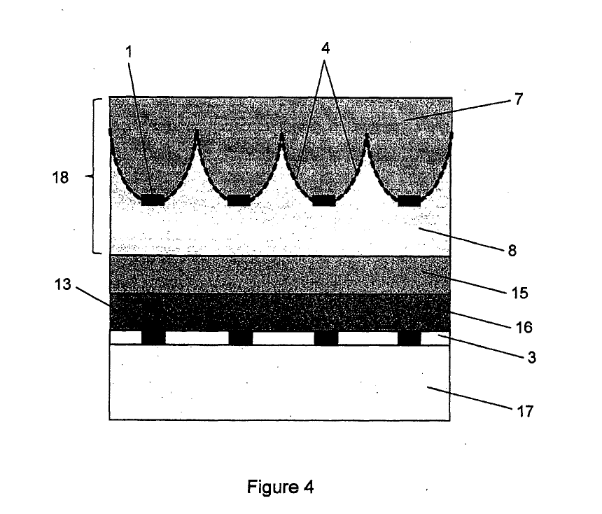

FIG. 4 is a schematic representation in cross section of the structure of an OLED display device according to the invention. The electroluminescent pixels 3, typically alternately composed of three different organic materials that emit in the blue, green and red are positioned on an electronic panel 17 for controlling said electroluminescent pixels 3, then encapsulated using a transparent material 16. The encapsulating layer 16 makes it possible to improve the stability of the materials used in manufacturing the pixels 3, in particular by forming a barrier to oxygen and water. The image light 6 is directly emitted by the electroluminescent pixels 3. In such a device, the upper polarizer is generally combined with a quarter-wave plate 15 that makes it possible to prevent the reflection of ambient light. This polarizer is replaced by the photovoltaic module according to the invention.

### Advantages of the Invention

It follows from the above that the invention achieves its stated goals. The invention describes an electronic display device including transflective polarizers that are capable of effectively concentrating a first component of the ambient light onto an array of photovoltaic active zones while being transparent to the second polarization of the image light at the openings of the photovoltaic module. Thus, the energy of the first component of the ambient light, usually lost through absorption in standard display devices, is converted to electrical energy.

Moreover, one advantage of the device that is a subject of the invention is that it produces energy independently of the light or dark state of the image.

Lastly, the surface fraction of photovoltaic active zones may be optimized so as to limit the reflection of the ambient light of the polarizing photovoltaic module toward the user.

### LIST OF THE REFERENCES USED IN THE FIGURES

| | |
|---|---|
| 1 | Photovoltaic active zone |
| 2 | Opening |
| 3 | Pixel |
| 4 | Semi-reflective polarizer |
| 5 | Ambient light |
| 6 | Image light |
| 7 | First transparent dielectric material layer |
| 8 | Second transparent dielectric material layer |
| 9 | Glass for protecting and controlling the electro-optical module |
| 10 | Electro-optical modulator |
| 11 | First polarizer |
| 12 | Backlight |
| 13 | Inter-pixel |
| 14 | Mirror |
| 15 | Quarter-wave plate |
| 16 | Encapsulating layer |
| 17 | Electronic control panel |
| 18 | Polarizing photovoltaic module |

1. A display device provided with a polarizing photovoltaic module including at least:
(a) a plurality of polarizers;
(b) a plurality of pixels which emit or transmit light referred to as image light;
(c) a plurality of photovoltaic active zones and a plurality of openings, two neighboring photovoltaic active zones forming an opening and said photovoltaic active zones being positioned between the pixels and the polarizers;
wherein said polarizers are semi-reflective and consist of one or more surfaces chosen from among planar, concave or convex surfaces which are parabolic, conical, pyramidal, tetrahedral, semicylindrical or cylindro-parabolic in shape, said polarizers being arranged so as both to concentrate, by reflection, a first linearly polarized component of the ambient light onto said photovoltaic active zones and to transmit, through said polarizing photovoltaic module, a second linearly polarized component of the ambient light or of the image light.

2. The display device as claimed in claim 1, wherein said polarizers are composed of an array of reflective strips, the widths of which and the distances separating them are advantageously less than 400 nanometers.

3. The display device as claimed in claim 1, wherein said photovoltaic active zones are positioned in the vicinity of the plane of maximum concentration of said polarizers.

4. The display device as claimed in claim 1, wherein the plurality of pixels are separated from one another by an inter-pixel matrix and in that said photovoltaic active zones are aligned with the inter-pixel matrix.

5. The display device as claimed in claim 1, wherein said photovoltaic active zones and said polarizers are organized into a continuous or discontinuous array of elementary patterns, defining any type of shape, in particular curved shapes, for example circular shapes, and/or planar shapes, for example polygonal, prismatic or hexagonal shapes.

6. The display device as claimed in claim 1, wherein said pixels consist of electro-optical modulators, optionally combined with color filters, or of electroluminescent materials.

7. The display device as claimed in claim 1, wherein said image light corresponds to a portion of the ambient light that is fully or partially reflected in the device and/or a portion of the light emitted by the device.

8. The display device as claimed in claim 1, wherein it additionally includes one or more other polarizers and/or a quarter-wave plate being used to polarize the image light.

9. The display device as claimed in claim 1, wherein it additionally includes a functional surface, for example an antireflective, anti-UV or touch-sensitive surface.

10. A method for manufacturing a portion of the display device as claimed in claim 1 composed of concentrators (4) and photovoltaic active zones, wherein it successively includes steps consisting of:
(a) providing a semitransparent photovoltaic module composed of a plurality of photovoltaic active zones and a plurality of openings, said photovoltaic active zones consisting of a plurality of thin films deposited on a transparent substrate;
(b) depositing a first transparent resist layer then structuring said resist so as to form the geometry of the concentrators;
(c) depositing a conformal layer of a reflective material on the structured face of said resist;
(d) etching the entire surface of the reflective layer in the form of strips and etching the surface at the tops of the concentrators;
(e) depositing a second, planarizing layer of transparent resist.

11. A fixed or portable, rigid or flexible electronic unit, wherein it comprises a display device according to claim 1.
